(19) United States
(12) Patent Application Publication
(10) Pub. No.: US 2026/0165115 A1
(43) Pub. Date: Jun. 11, 2026

(54) SEMICONDUCTOR DIE AND METHOD OF MANUFACTURING THE SAME

(71) Applicant: Infineon Technologies AG, Neubiberg (DE)

(72) Inventors: Thomas SÖLLRADL, Arnoldstein (AT); Jochen HILSENBECK, Villach (AT); Thomas GANNER, Krumpendorf am Wörthersee (AT); Philipp ROSS, München, Bayern (DE); Konrad SCHRAML, Feldkirchen (DE); Dethard PETERS, Höchstadt (DE); Tobias WASSERMANN, Soest, Hattrop (DE)

(21) Appl. No.: 19/181,853

(22) Filed: Apr. 17, 2025

(30) Foreign Application Priority Data
Apr. 18, 2024 (DE) 102024203635.8

(51) Int. Cl. H10W 20/47; H10P 50/00; H10W 20/00; H10W 20/42; H10W 20/43; H10W 72/90

(52) U.S. Cl. CPC H10W 20/47; H10P 50/73; H10W 20/081; H10W 20/422; H10W 20/43; H10W 72/942

(57) ABSTRACT

The disclosure relates to a semiconductor die, comprising a silicon carbide (SiC) semiconductor body in which a device structure with a load terminal is formed; a metallization on a first side of the SiC semiconductor body, in which a load pad is formed; a passivation system on the metallization, which has an opening on the load pad; wherein the passivation system, as viewed in a sectional plane perpendicular to a lateral edge of the load pad, extends between an outer lateral position x₁ aside the load pad and an inner lateral position x₂ on the load pad, wherein an interruption is provided in at least one layer of the passivation system at an interruption position xᵢ between the lateral edge of the load pad and the inner lateral position x₂.

### RELATED APPLICATION

This application claims priority to German Patent Application No. 102024203635.8, filed on Apr. 18, 2024, entitled “SEMICONDUCTOR DIE AND METHOD OF MANUFACTURING THE SAME”, which is incorporated by reference herein in its entirety.

### TECHNICAL FIELD

The present disclosure relates to a semiconductor die comprising a semiconductor body.

### BACKGROUND

In embodiments of this application, the semiconductor body is made of silicon carbide (SiC) which has a comparably wide band gap, e.g. compared to silicon. This can for instance be of interest for power semiconductor devices in high voltage and/or high current applications. In the semiconductor body, a device structure with a load terminal or terminals can be formed, for example a transistor structure having a source terminal and a drain terminal. For a wiring and contacting of the device structure, a metallization can be formed on the semiconductor body.

### SUMMARY

Examples of the present application are directed at an advantageous semiconductor die.

In an embodiment, a semiconductor die with a semiconductor body comprises a metallization in which a load pad is formed. A passivation system is provided on the metallization, wherein the passivation system has an opening on the load pad (e.g. for a later contacting in a package or other mounting structure). As viewed in a vertical cross-section, the passivation system may extend between an outer lateral position x₁ aside the load pad, e.g. at or close to a lateral edge of the die, and an inner lateral position x₂ on the load pad. In an embodiment, an interruption is provided in at least one layer of the passivation system on the load pad, e.g. as viewed in the vertical cross-section at an interruption position xᵢ between a lateral edge of the load pad and the inner lateral position x₂. In other words, the interruption may be arranged laterally outside of the opening in the passivation system but still on the load pad.

The interruption can for instance reduce a stress propagation and, in consequence, delamination risk, for example of an inorganic/hard passivation layer of the passivation system. The mechanical stress may increase with increasing metal area, wherein specifically high stress values can result at the corners and/or lateral edges of the load pad. The interruption arranged on the load pad, i.e. laterally between the opening of the passivation system and the lateral edge of the load pad, can reduce the stress level in the passivation system there. The interruption is for instance smaller than the opening which the passivation system has on the load pad. As viewed in the sectional plane, the opening may for instance have a width of at least 0.2 mm, 0.5 mm or 1 mm (possible upper limits being several millimeters or even centimeters), whereas the interruption may have a width of several micrometers or tens of micrometers, by way of example.

Further embodiments and features are provided in the claims and throughout this disclosure. Therein, the individual features shall be disclosed independently of a specific claim category, the disclosure relates to apparatus and device aspects but also to method and use aspects. If for instance a die manufactured in a specific way is described, this is also a disclosure of a respective manufacturing process, and vice versa. In general words, embodiments of the present application aim at providing an interruption in at least one layer of a passivation system, e.g. on a load pad.

The load pad formed in the metallization may be connected to the load terminal of the device structure in the semiconductor body. The load terminal connected to the load pad may be a first load terminal arranged at a first side of the semiconductor body and the device structure can comprise a second load terminal, e.g. at a vertically opposite second side of the semiconductor body. The device structure can for instance be a FET having a source terminal/region and a drain terminal/region in the semiconductor body, e.g. the source region at the first side of the semiconductor body and the drain region at the second side thereof. In other words, the load pad in the metallization may be a source pad connected to a source terminal of the device structure.

In addition to the source region and the drain region, the device may comprise a body region to which a gate electrode capacitively couples. Additionally, a drift region may be arranged between the body region and the drain region, e.g. made of the same doping type but with a lower concentration than the drain region. The source region and drain region and, if present, drift region may be made of a first doping type, the body region made of a second doping type. In the illustrated embodiments, the first doping type is n-type and the second doping type is p-type.

When reference is made to a “vertical cross-section”, this may relate to a sectional plane perpendicular to the lateral edge of the load pad. This “lateral edge” can for instance be an outer rim of an upper surface of the metallization, which upper surface faces away from the semiconductor body; the inner lateral end of the passivation system can for instance lie on the same upper surface of the metallization, i.e. laterally inside of the lateral edge.

As seen in a vertical top view, the interruption may for instance be a slot, e.g. enclosing an angle with or extending in parallel to the lateral edge of the load pad. The slot may extend around the load pad partially or completely. As viewed in the sectional plane, one single interruption or a plurality of interruptions may be provided in the at least one layer of the passivation system between the lateral edge of the load pad and the inner lateral position on the load pad. In other words, as seen in the vertical top view, one single slot or a plurality of slots may be arranged between a respective lateral edge of the load pad and the opening.

The passivation system “on” the metallization is not necessarily disposed directly on the metallization, i.e. not necessarily directly adjacent to the metallization. In other words, an additional layer may be arranged in between, for instance an adhesion promoter layer, e.g. aluminum oxide layer. The adhesion promoter layer can for instance improve an adhesion of the passivation system on the metallization, e.g. of an inorganic passivation layer system or stack on a copper layer of the metallization.

The semiconductor body may comprise a semiconductor substrate, for instance in combination with one or a plurality of epitaxial layers thereon. In general, the semiconductor body may be a silicon (Si) or gallium nitride (GaN) semiconductor body, whereas embodiments of the present application relate to a semiconductor die with a silicon carbide (SiC) semiconductor body. This can allow for high voltages in operation of the device or device structure so that the aforementioned delamination issues can be especially relevant.

In an embodiment, the passivation system comprises an inorganic passivation layer system and an organic layer on the inorganic passivation layer system. The “inorganic passivation layer system” may be a single inorganic layer or a stack of inorganic layers. Basically, the “at least one layer” in which the interruption is provided may be the organic layer, for instance cured imide might cause a certain mechanical stress and the interruption may allow for a stress relief in the imide.

In an embodiment, however, the interruption is provided at least in the inorganic passivation layer system. In other words, the interruption is provided in at least one inorganic layer of the inorganic passivation layer system, e.g. in a single inorganic layer or in a stack of inorganic layers. In general, this may be combined with an interrupted organic/imide layer, the interruption as viewed in the sectional plane intersecting the at least one inorganic layer and also the organic/imide layer.

In an embodiment, however, the organic layer is uninterrupted at the interruption position, e.g. fills the interruption in the inorganic passivation layer system. In other words, the interruption as viewed in the sectional plane intersects only the at least one inorganic layer, e.g. intersects the inorganic layer stack, wherein the organic layer covers the interruption. The organic layer, e.g. imide layer, as viewed in the sectional plane, may fill the interruption, which can for instance reduce a risk of residuals in the interruption.

In an embodiment, the inorganic passivation layer system comprises a silicon nitride layer and a silicon oxide layer. The silicon nitride layer may be arranged below or on the silicon oxide layer. In an embodiment, the silicon oxide layer is arranged on a first silicon nitride layer, wherein a second silicon nitride layer is arranged on the silicon oxide layer, the silicon oxide layer for instance directly on the first silicon nitride layer and/or the second silicon nitride layer directly on the silicon oxide layer. The first silicon nitride layer may for instance be thinner than the silicon oxide layer and/or second silicon nitride layer. Independently of these geometrical details, the silicon oxide layer may for instance be an undoped silicon oxide layer, e.g. undoped silicon glass (USG).

As discussed above, the passivation system, which may comprise the inorganic passivation layer system and the organic layer thereon, is arranged on the metallization. Below the metallization, e.g. between the metallization and the SiC semiconductor body an insulating layer may be arranged. The insulating layer may serve as an interlayer dielectric, e. g. define a contact structure between the metallization and the semiconductor body. It may comprise an oxide layer, for example a borophosphosilicate glass (BPSG) layer. In other words, the insulating layer may comprise a doped oxide layer, for example in addition to an undoped oxide layer. The insulating layer may for instance have a total thickness of at least 0.5 μm and/or at most 3 μm.

In an embodiment, the organic layer is an imide layer. The imide can for instance be a photosensitive polyimide precursor. The organic layer, e.g. imide layer, can for instance have a thickness of at least 1 μm, further lower limits being for instance at least 2 μm, 3 μm, 4 μm or 5 μm. Possible upper limits may for instance be not more than 50 μm, 40 μm, 30 μm or 25 μm.

In an embodiment, an adhesion promoter layer is arranged on the inorganic passivation layer system below the organic layer. In other words, the organic layer is not arranged directly on the inorganic passivation layer system but with an adhesion promoter layer in between. The adhesion promoter layer may be arranged directly on the inorganic passivation layer system and/or the organic layer may be arranged directly on the adhesion promoter layer. In other words, the adhesion promoter layer may be arranged directly on the uppermost inorganic layer of the passivation layer system, e.g. silicon nitride layer.

The adhesion promoter layer between the inorganic passivation layer system and the organic layer shall also be disclosed independently of an interruption in the passivation system. Consequently, it shall be disclosed a semiconductor die, comprising: a semiconductor body; a metallization on a first side of the semiconductor body; an inorganic passivation layer system on the metallization; an adhesion promoter layer on the inorganic passivation layer system; an organic layer on the adhesion promoter layer. As to possible embodiments and additional features, e.g. in terms of materials, thicknesses and so on, reference is made to the disclosure as a whole.

The adhesion promoter layer on the inorganic passivation layer system can for instance allow for uniform adhesion properties, e.g. in comparison to the interface on the metallization which may be provided with the adhesion promoter layer as well, see in detail below. Independently of whether combined with the interruption or not, the adhesion promoter layer may for example have a thickness of at most 30 nm, further upper limits being for instance 20 nm or 15 nm. A possible lower limit of the adhesion promoter layer thickness may be 5 nm.

In an embodiment, the adhesion promoter layer is an aluminum oxide layer. Optionally, it may also be deposited onto the metallization and have for instance a protection function there, see in detail below.

In an embodiment, the interruption in the at least one layer of the passivation layer system is, as viewed in the sectional plane, spaced by at least 1 μm laterally inwards from the lateral edge of the load pad and/or is spaced by at least 1 μm laterally outwards from the inner lateral position to which the passivation system extends on the load pad. Further lower limits may be at least 2 μm or 3 μm, possible upper limits being for instance at most 50 μm, 30 μm or 20 μm.

Generally, “outward(s)” and “outermost” may relate to the lateral position with respect to the respective lateral edge of the semiconductor body, i.e. mean closer or closest to this lateral edge. As viewed in the vertical cross-section, the at least one layer, in which the interruption is provided, may have an outer portion laterally outside of the interruption and an inner portion laterally inside of the interruption (but still outside of the active area). In other words, a respective layer, e.g. inorganic or organic layer, intersected by the interruption may extend on both sides of the interruption as viewed in the vertical cross-section. Generally, the elements discussed with respect to their relative position are for instance arranged on the same side of an active area of the die, i.e. at the same lateral edge of the semiconductor body. Therein, similar structures may be arranged at the other lateral edges of the semiconductor body, which, however, is not mandatory. Generally, when the passivation system comprises an inorganic passivation layer system and an organic layer, the outer lateral ends of the inorganic passivation layer system and of the organic layer as viewed in the vertical cross-section can lie flush (at the outer lateral position) and/or the inner lateral ends of the inorganic passivation layer system and of the organic layer as viewed in the vertical cross-section can lie flush (at the inner lateral position). Alternatively, when a layer of the passivation system extends further outwards and/or inwards, the outer lateral position is arranged at the outer lateral end of the layer extending further outwards and/or the inner lateral position is arranged at the inner lateral end of the layer extending further inwards. For instance, the outer lateral position may be arranged at the outer lateral end of the organic layer and/or the inner lateral position may be arranged at the inner lateral end of the organic layer.

In an embodiment, the interruption has a width of at least 0.5 μm, further lower limits being for instance at least 1 μm, 2 μm, 3 μm, 4 μm or 5 μm. Alternatively or in addition, possible upper limits may be at most 50 μm, 40 μm or 30 μm. The width of the interruption may be taken in the sectional plane, for instance at the lower end or bottom of the interruption (e.g. in the lowermost inorganic layer intersected by the interruption).

In an embodiment, the metallization in the area of the load pad is formed with a step. Laterally outside of the step, e.g. closer to a lateral edge of the semiconductor body or die, the load pad has a first thickness t₁. Laterally inside of the step, e.g. at a larger distance from the lateral edge of the semiconductor body or die, the load pad has a second thickness t₂. Therein, t₁ is smaller than t₂. In other words, the load pad has a smaller thickness t₁ in an edge portion of the load pad and a larger thickness in a central portion of the load pad. The latter may, for example, have advantages in terms of thermal management or mounting and bonding, wherein the smaller thickness in the edge portion can for instance reduce a topology of the passivation system extending onto the load pad.

In an embodiment, the inner lateral position x₂, to which the passivation system extends, is arranged laterally outside of the step. In other words, the passivation system as viewed in the sectional plane extends laterally onto the load pad but ends in the edge region thereof, where the load pad has the thickness t₁. As viewed in a sectional plane, the passivation system covers the lateral edge of the load pad but not the step.

In an embodiment, an inorganic layer or inorganic layer stack covers a flank of the step in the load pad. The inorganic layer may be, or the inorganic layer stack may comprise, a silicon nitride layer and/or a silicon oxide layer. Independently of a specific material, covering the flank can, depending for example on the metallization stack or structure, for instance reduce an underetch risk or protect an interface, e.g. between a first and a second copper layer, see in further detail below. Even when an electrical field originating from a backside potential reaching up to the first side at the lateral edge of the semiconductor body is reduced in an edge termination area or structure, a residual field strength may remain on the load pad, which can for instance be relevant in terms of migration or diffusion processes.

The flank covered by an inorganic layer or layer stack shall also be disclosed independently of the interruption in the passivation system. In other words, it shall be disclosed a semiconductor die, comprising: a semiconductor body; a metallization on a first side of the semiconductor body, in which a load pad is formed; wherein the metallization in the area of the load pad is formed with a step, the load pad having a first thickness t₁ laterally outside of the step and a second thickness t₂ laterally inside of the step, where t₁ is smaller than t₂, wherein an inorganic layer or layer stack covers a flank of the step. As to possible embodiments and additional features, reference is made to the disclosure as a whole.

In an embodiment, the metallization comprises a copper layer. The copper layer may be part of a copper layer system which can for instance comprise a sputter-deposited copper layer and one or a plurality of bath-deposited copper layers on top. A “bath-deposited” copper layer can for instance be an electrochemically deposited copper layer, i.e. ECD layer (though an electroless deposition is generally also conceivable). In an embodiment, the metallization comprises a first bath-deposited copper layer and a second bath-deposited copper layer deposited onto the first bath-deposited copper layer, wherein the second bath-deposited copper layer may be structured with respect to the first bath-deposited copper layer. In other words, the second bath-deposited copper layer may form the step in the load pad.

For a structuring of the second bath-deposited copper layer, a mask may be provided on the first bath-deposited copper layer prior to the deposition of the second bath-deposited copper layer. The step in the load pad can be formed at a lateral edge of the second bath-deposited copper layer, which is displaced inwards with respect to a lateral edge of the first bath-deposited copper layer. Alternatively, however, a copper layer or layers may be sputter-deposited, independently of whether or not a bath-deposited copper layer system is applied subsequently. In other words, a sputter-deposited copper layer or layers may be combined with a bath-deposited copper layer(s) or the copper metallization as a whole may be sputter-deposited. Also in case of the sputter-deposited copper metallization, an upper copper layer may be structured with respect to a copper layer below to form a step.

In sum, independently of whether sputter-and/or bath-deposited, all copper layers of the metallization can for instance have a thickness of at least 3 μm, further lower limits being for instance 5 μm or 7 μm. By way of example, upper limits may be 25 μm or 20 μm. Below the lowermost copper layer, e.g. sputter-deposited copper layer, a barrier layer system of the metallization may be arranged (e.g. comprising a Ti/TiN layer).

In an embodiment, a runner is formed aside the load pad in the metallization, e.g. a conductor line extending aside the load pad (for instance in parallel to the lateral edge of the load pad and/or lateral edge of the die). The runner may be a gate runner electrically connected to a gate electrode or gate electrodes, e.g. a respective gate electrode of a respective device cell in the active area. Alternatively, the runner may be a source runner, e.g. be electrically connected to a respective source terminal of a respective device cell in the active area. In an embodiment, a gate runner and a source runner are formed aside the load pad, e.g. the source runner laterally outside of the gate runner.

In an embodiment, a method of manufacturing a semiconductor die comprises:
I) forming a device structure with a load terminal in a semiconductor body;
II) forming a metallization with a load pad on a first side of the semiconductor body;
III) forming a passivation system on the metallization, which has an opening on the load pad, wherein an interruption is provided in at least one layer of the passivation system at an interruption position xᵢ between a lateral edge of the load pad and the opening.

As to possible embodiments and details, reference is made to the disclosure as a whole.

In an embodiment, step III) comprises:
i) forming an inorganic passivation layer system; and
ii) forming an organic layer, e.g. imide layer, on the inorganic passivation layer system.

In an embodiment, the interruption is formed in the inorganic passivation layer system by
providing a mask on the inorganic passivation layer system after step i);
etching the interruption defined by the mask into the inorganic passivation layer system.

The mask may be structured to define the interruption, e.g. have an opening where the interruption is to be etched into the inorganic passivation layer system below. In addition to defining the interruption or interruptions, the mask may define an inner and/or outer lateral edge of the inorganic passivation layer system, e.g. as viewed in the sectional plane. Independently of these details, the mask defining the interruption in the etch step may be removed prior to forming the organic layer, e.g. imide layer, in step ii).

Alternatively, in embodiments relating to a passivation system without an interruption, the organic layer of the passivation system, e.g. imide layer, can for instance be used as an etch mask defining an inner and/or outer lateral end of the inorganic passivation layer system and may remain on the inorganic passivation layer system after the etch step.

In an embodiment, a method of manufacturing a semiconductor die comprises:
a) forming a metallization with a load pad on a first side of a semiconductor body;
b) forming an inorganic passivation layer system on the metallization, which has an opening on the load pad;
c) after step b), forming a protection layer in the opening on the load pad.

As to additional embodiments and features, reference is made to the disclosure as a whole.

The protection layer may have a thickness of at most 30 nm, further upper limits being for instance 20 nm and 15 nm. Providing a comparably thin protection layer can for instance have advantages in a mounting or bonding process later on, e.g. allow for a contact formation to a wire or clip (even in case of an electrically isolating protection layer).

Possible lower limits of the protection layer thickness may be 3 nm or 5 nm, by way of example.

The protection layer can for instance reduce or avoid a dissolving and rinsing out of metallization atoms or particles, e.g. copper, in later manufacturing steps, for example during back end of line assembly (for example when rinsing with a solvent or acid, e.g. CH₂O₂). In more general words, the protection layer can provide a protection, e.g. against an oxidation due to processes in later manufacturing steps. Depositing the protection layer after the inorganic passivation layer system has been deposited and structured, e.g. etched away locally from the load pad, can for instance allow for a homogeneous protection layer over the opening on the load pad, e.g. also in case of a load pad with a step as discussed above.

Further, the same layer serving as the protection layer in the opening on the load pad may serve as an adhesion promoter layer on the inorganic passivation layer system below the organic layer, see in detail above. In an embodiment, the protection layer formed in step c) is an aluminum oxide layer. It may in any case be deposited into the opening on the load pad, in an embodiment it is simultaneously deposited onto the inorganic passivation layer system.

In an embodiment, prior to forming the protection layer in step c), a temporary protection layer present on the metallization is removed in the opening from the load pad. The temporary protection layer may be an aluminum oxide layer as well, e.g. with a thickness between 3 nm-30 nm. Aside the opening, i.e. below the inorganic passivation layer system, it may remain on the metallization, e.g. improve an adhesion of the inorganic passivation layer system on the metallization.

Any of the methods or method steps discussed above may be applied for manufacturing a semiconductor die discussed above, e.g. with or without an interruption in the passivation system and/or with or without a step in the load pad and coverage of the step and/or with or without an adhesion promoter layer on the inorganic passivation layer system below the organic layer.

### BRIEF DESCRIPTION OF THE DRAWINGS

Below, the semiconductor die and method of manufacturing are explained in further detail by means of exemplary embodiments. Therein, the individual features can also be relevant in a different combination.

FIG. 1 shows a cross-sectional view of a semiconductor die comprising a semiconductor body, a metallization and a passivation system on the metallization;

FIG. 2 shows a more detailed view of a passivation system on a load pad in the metallization;

FIG. 3 shows a schematic cross-section of a device formed in an active area of a die;

FIGS. 4a-e illustrate different steps of manufacturing a semiconductor die with a passivation system comprising an inorganic passivation layer system and an organic layer;

FIG. 5a,b summarize some manufacturing steps in a flow diagram.

### DETAILED DESCRIPTION

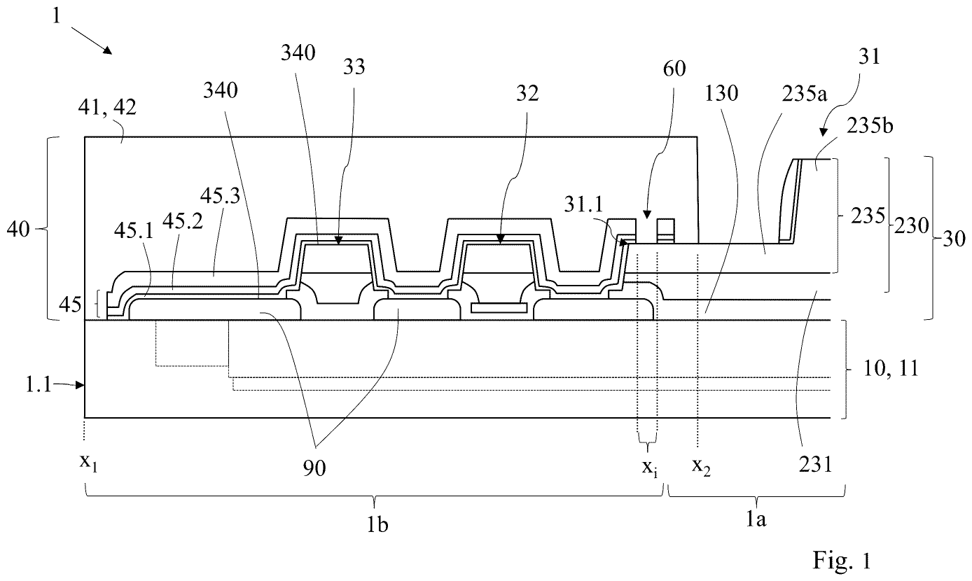

FIG. 1 shows a portion of a semiconductor die 1 in a vertical cross-section. The semiconductor die 1 comprises a semiconductor body 10 which is a silicon carbide (SIC) semiconductor body 11 in the example shown. On a first side 10.1 of the semiconductor body 10, an insulating layer 90 is arranged. Further, a metallization 30 is formed on the semiconductor body 10, which comprises a barrier layer system 130. On the barrier layer system 130, a copper layer system 230 is arranged, which in the example shown comprises a sputter-deposited copper layer 231 and a bath-deposited copper layer system 235 with a first bath-deposited copper layer 235a and a second bath-deposited copper layer 235b.

In detail, the cross-sectional view of FIG. 1 lies at a lateral edge 1.1 of the die 1, wherein an inactive area 1b is arranged laterally between the lateral edge 1.1 of the die 1 and an active area 1a shown on the right in FIG. 1. In the active area 1a, transistor device cells may be arranged (see in detail below). In the active area 1a, a load pad 31 may be formed in the metallization 30, for example a source pad connected to a source terminal of the device or device cells. In the inactive area 1b, a gate runner 32 and/or a source runner 33, each extending along the active area 1a, may be formed in the metallization 30.

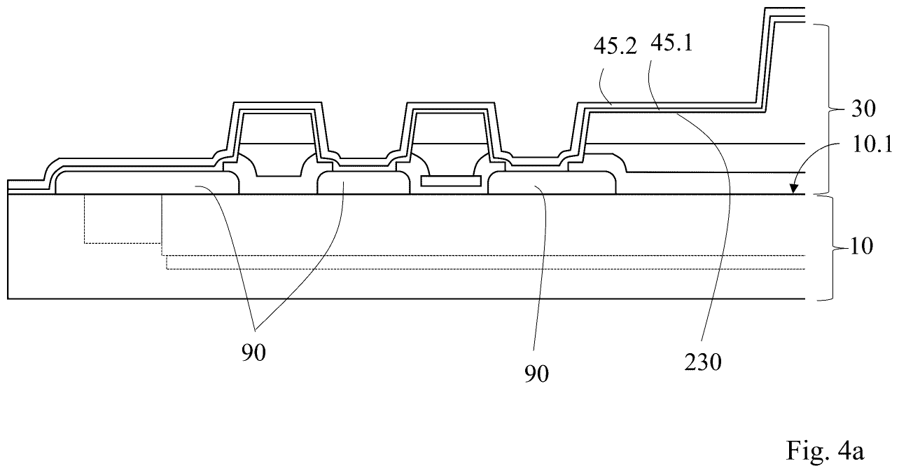

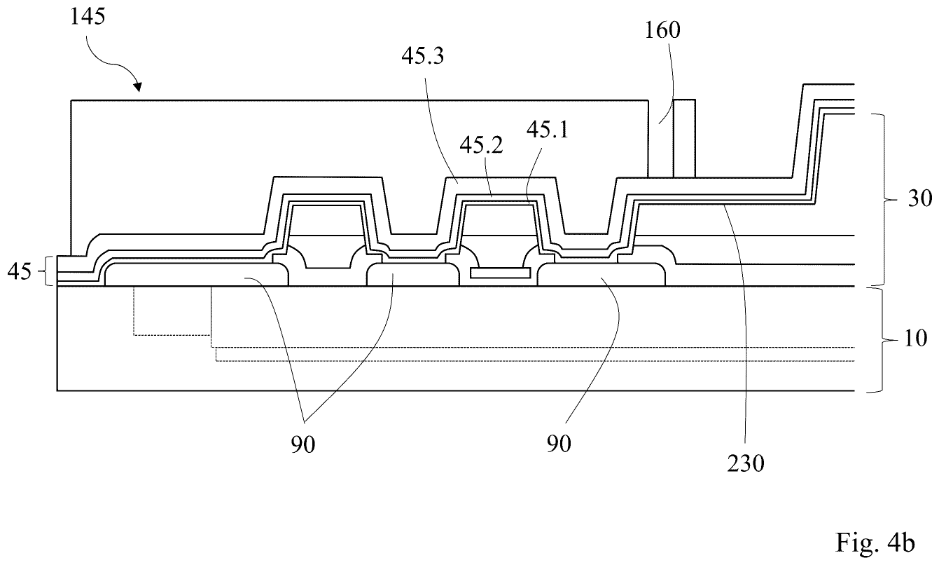

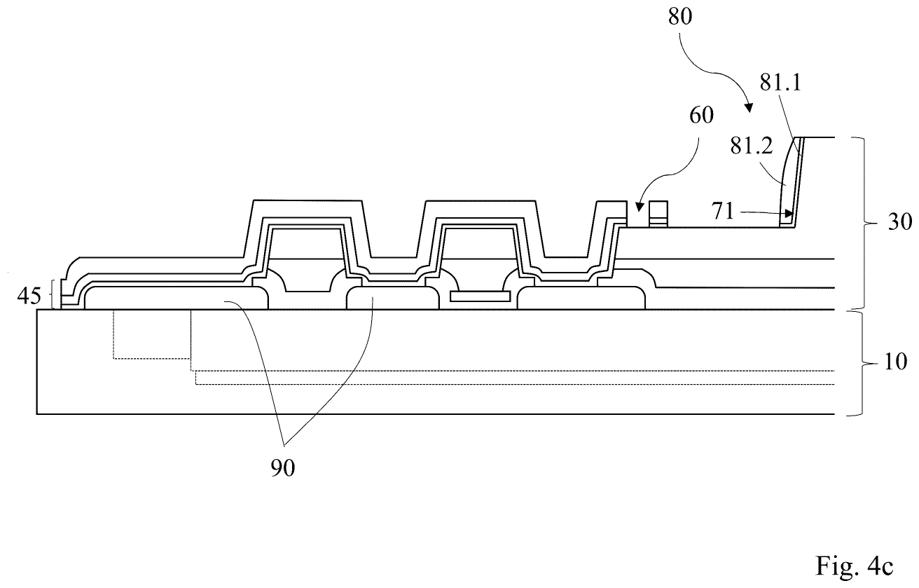

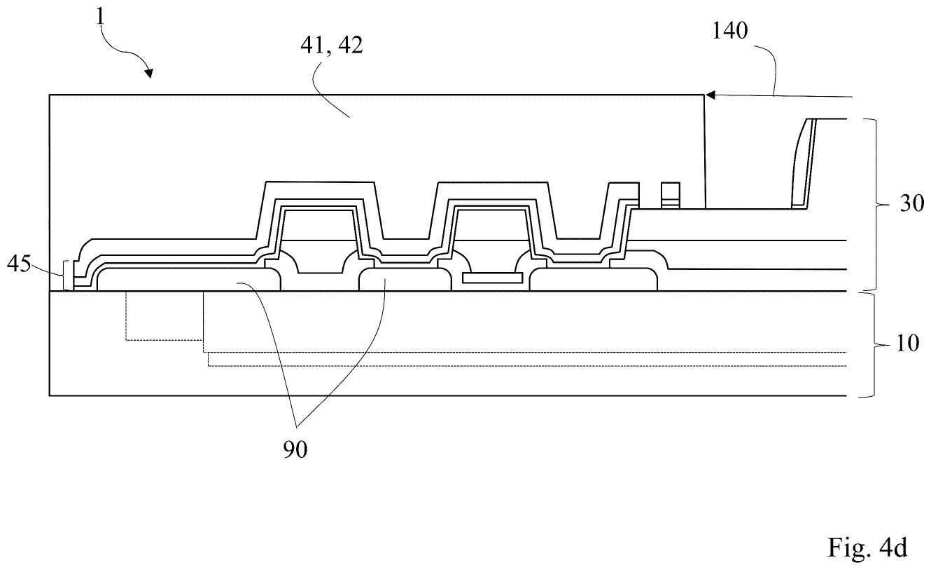

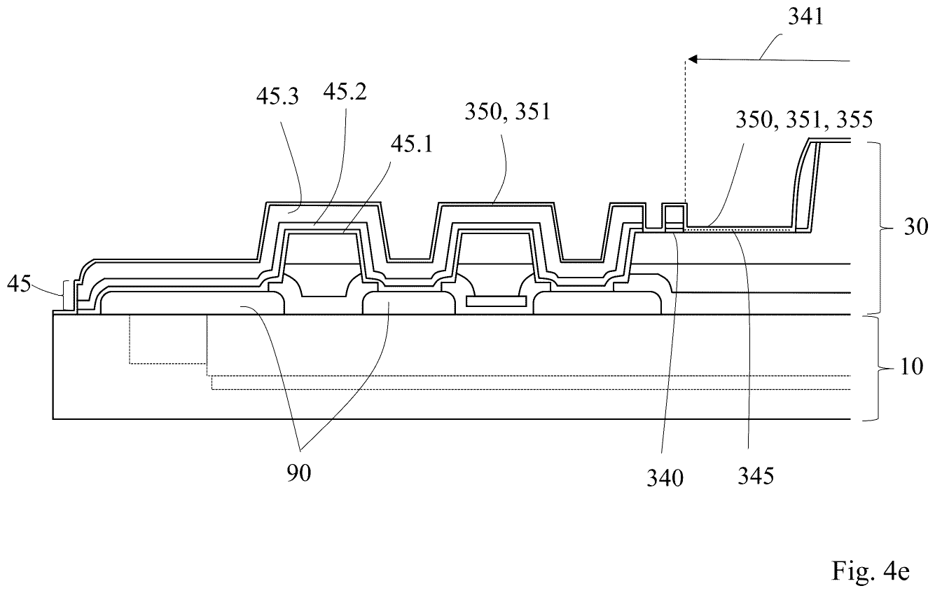

On the metallization 30, a passivation system 40 is arranged, which in the example shown comprises an inorganic passivation layer system 45 and an organic layer 41, e.g. imide layer 42, on the inorganic passivation layer system 45. As discussed in further detail with reference to FIG. 4e, an additional adhesion promoter layer can be arranged in between (not shown here).

The inorganic passivation layer system 45 shown comprises a first silicon nitride layer 45.1, an undoped silicon oxide layer 45.2 directly on the first silicon nitride layer 45.1, and a second silicon nitride layer 45.3 directly on the undoped silicon oxide layer 45.2. The passivation system 40 covers the gate runner 32 and source runner 33 and covers also the insulating layer 90 made of doped oxide (e.g. borophosphosilicate glass, BPSG). In the example shown, an aluminum oxide layer 340 (shown only as a line in FIG. 1) is arranged below the inorganic passivation layer system 40, i.e. on the insulating layer 90 and also on the metallization 30.

The sectional plane of FIG. 1 lies perpendicular to a lateral edge 31.1 of the load pad 31. The passivation system 40 extends between an outer lateral position x₁ aside the load pad and an inner lateral position x₂ which lies on the load pad 31, i.e. covers the lateral edge 31.1 of the load pad 31. In the embodiment shown, an interruption 60 is provided in at least one layer 41, 42, 45.1-45.3 of the passivation system 40, in this case the interruption 60 intersects the inorganic passivation layer system 45 completely. It is arranged at an interruption position xᵢ laterally between the lateral edge 31.1 of the load pad 31 and the inner lateral position x₂.

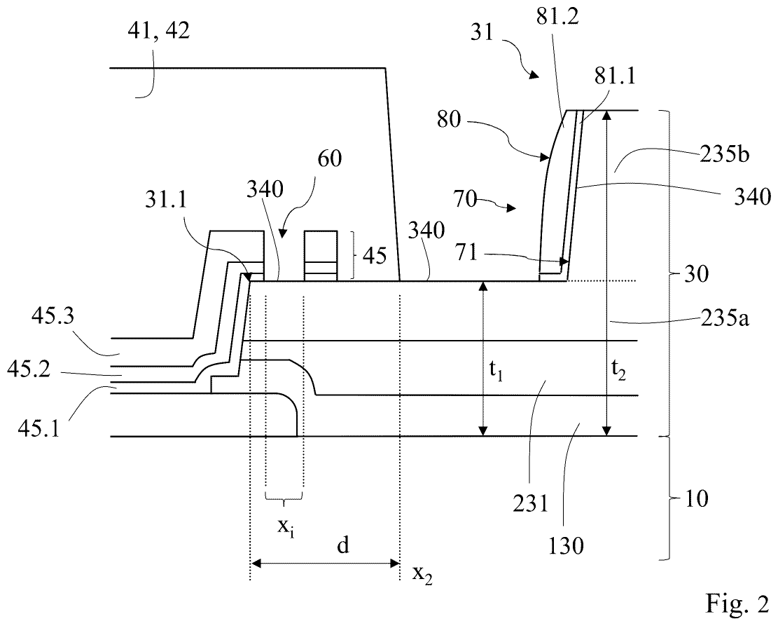

The organic layer 41, e.g. imide layer 42, is not interrupted at the interruption position xᵢ and fills the interruption 60 in the inorganic passivation layer system 45, see also the detailed view of FIG. 2. At the bottom of the interruption 60 in the inorganic passivation layer system 45, the organic or imide layer 41, 42 may lie directly on the aluminum oxide layer 340 which covers the metallization 30. In the example shown, one single interruption 60 is provided in the passivation system 40, i.e. inorganic passivation layer system 45, though in practice a plurality of interruptions may be staggered aside each other between the lateral edge 31.1 of the load pad 31 and the inner lateral position x₂.

A lateral distance d between the lateral edge 31.1 of the load pad 31 and the inner lateral position x₂ can for instance be at least 100 μm or 200 μm (upper limits may be several millimeter or for instance at most 1 mm). In the detailed view of FIG. 2, a distance d between the lateral edge 31.1 of the load pad 31 and the inner lateral position x₂ is referenced, wherein the interruption position x₁ lies within this distance d. For illustration, in absolute values the distance d may be several hundred micrometers and the interruption 60 may have a width w of a few micrometers or a few tens of micrometers.

In the load pad 31, a step 70 is formed. Laterally outside of the step 70, the load pad 31 has a first thickness t₁ and laterally inside of the step 70 it has a larger thickness t₂. In the example shown, the step 70 is formed by the second bath-deposited copper layer 235b which is structured with respect to the first-deposited copper layer 235a, namely offset inwards (away from the lateral edge 1.1 of the die 1). The passivation system 40 extends onto the load pad 31 but ends on the first bath-deposited copper layer 235a, the inner lateral position x₂ lying laterally outside of the step 70.

In the example shown, a flank 71 of the step, which faces laterally outwards, is covered by an inorganic layer 81.1, 81.2, e.g. stack 80 of inorganic layers 81.1, 81.2. The inorganic layers 81.1, 81.2, or the inorganic layer stack 80, may be arranged directly on the flank 71 or, as shown in FIG. 2, directly on the aluminum oxide layer 340 (represented only as a line) which extends on the metallization 30 and also on the flank 71. The first inorganic layer 81.1 arranged directly on the aluminum oxide layer 340 may be a silicon nitride layer on which the second inorganic layer 81.2 being a silicon oxide layer (e.g. USG) is arranged.

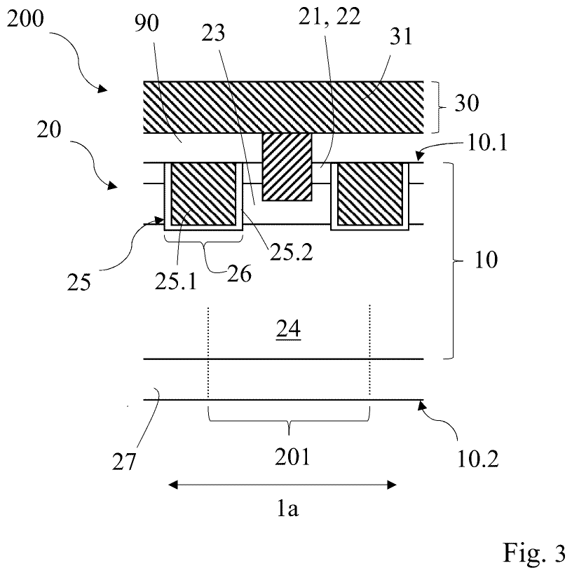

FIG. 3 illustrates a possible device 200 and device structure 20 formed in the active area 1a of the die 1, e.g. below the load pad 31 (see FIG. 1 for comparison). In the semiconductor body 10, e.g. SiC semiconductor body 11, a load terminal 21 is formed at the first side 10.1, which is a source region 22 in the example shown. At the vertically opposite second side 10.2, a drain region 27 is arranged, wherein a body region 23 disposed below the source region 22 and a drift region 24 is arranged between the body region 23 and the drain region 27.

A gate region 25 comprising a gate electrode 25.1 and a gate dielectric 25.2 capacitively coupling the gate electrode 25.1 to the body region 23 is arranged in a trench 26. Via a voltage applied to the gate electrode 25.1, a channel formation in the body region 23 and, in consequence, current flow between the source region 22 and drain region 27 can be controlled. The device 200 may comprise a plurality of device cells 201 connected in parallel.

FIGS. 4a-e illustrate some steps for manufacturing a semiconductor die having a semiconductor body, and a metallization and a passivation system. In FIG. 4a, the insulating layer 90 has already been deposited onto the first side 10.1 of the semiconductor body 10 and the metallization 30 has been formed. Onto the metallization 30, the aluminum oxide layer 230 has been deposited (shown only as a line) and the silicon nitride layer 45.1 and the silicon oxide layer 45.2 have been deposited.

Prior to covering the silicon oxide layer 45.2 by the second silicon nitride layer 45.3 as shown in FIG. 4b, the silicon oxide layer 45.2 may be etched back (not shown in detail here). In FIG. 4b, the inorganic passivation layer system 45 has been deposited but not structured yet. For that purpose, a mask 145 is provided on the inorganic passivation layer system 45. The mask 145 has an opening 160 defining where the interruption is to be etched into the inorganic passivation layer system 45. Further, the mask 145 defines an inner and outer lateral end of the inorganic passivation layer system 45, i.e. where the inorganic passivation layer system 45 is to be opened on the load pad 31.

FIG. 4c illustrates the inorganic passivation layer system 45 after the etch step, i.e. after the interruption 60 has been etched into the inorganic passivation layer system 45. The mask has already been removed. E.g. applying an anisotropic etch step may leave the inorganic layers 81.1, 81.2 on the flank 71 of the step 80.

FIG. 4d illustrates the die 1 after the organic layer 41, e.g. imide layer 42 has been deposited, structured and cured. The organic or imide layer 41, 42 defines the opening 140 on the load pad 31.

FIG. 4e illustrates an additional process variant that may be applied prior to the deposition of the organic or imide layer 41, 42, i.e. prior to the situation illustrated in FIG. 4d. As illustrated in FIG. 4e, an adhesion promoter layer 350 may be deposited onto the inorganic passivation layer system 45, for example an aluminum oxide layer 351. On the load pad 31, the inorganic passivation layer system 45 has an opening 341. There, prior to the deposition of the adhesion promoter layer 350, the aluminum oxide layer 340, e.g. temporary protection layer 345, may be removed prior to the deposition of the adhesion promoter layer 350. Independently of whether or not the aluminum oxide layer 340 is removed in the opening 341, the adhesion promoter layer 350 e.g. aluminum oxide layer 351, may serve as a protection layer 355 there. In other words, the same layer may serve as an adhesion promoter on the inorganic passivation layer system 45 and as a protection where the passivation is opened and the metallization is exposed.

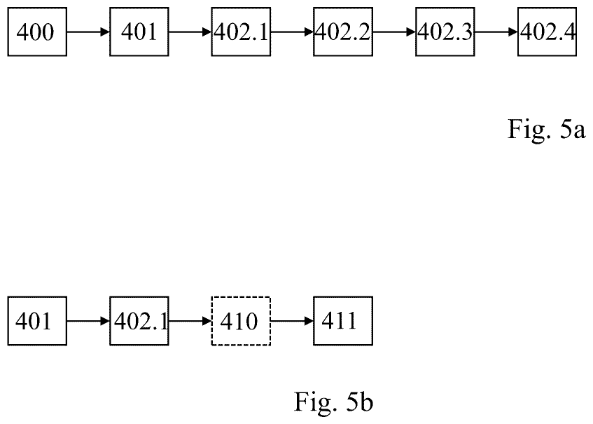

FIG. 5a summarizes some manufacturing steps in a flow diagram. After forming 400 a device structure in the semiconductor body, the metallization may be formed 401 on the semiconductor body. Thereon, the passivation system is formed 402 e.g. by forming 402.1 the inorganic passivation system, providing 402.2 a mask on the inorganic passivation layer system, etching 402.3 the interruption into the inorganic passivation layer system, and thereafter forming 402.4 the organic layer on the inorganic passivation layer system.

FIG. 5b illustrates some manufacturing steps in a flow diagram. After forming 401 the metallization on the semiconductor body and forming 402.1 the inorganic passivation layer system on the metallization, a protection layer may be formed 411 in an opening of the inorganic passivation layer system on the load pad. Optionally, a temporary protection layer may be removed 410 in advance.

1. A semiconductor die, comprising:
a semiconductor body in which a device structure with a load terminal is formed;
a metallization on a first side of the semiconductor body, in which a load pad is formed; and
a passivation system on the metallization, which has an opening on the load pad,
wherein the passivation system, as viewed in a sectional plane perpendicular to a lateral edge of the load pad, extends between an outer lateral position x₁ aside the load pad and an inner lateral position x₂ on the load pad,
wherein an interruption is provided in at least one layer of the passivation system at an interruption position xᵢ between the lateral edge of the load pad and the inner lateral position x₂.

2. The semiconductor die of claim 1, wherein the passivation system comprises an inorganic passivation layer system and an organic layer on the inorganic passivation layer system.

3. The semiconductor die of claim 2, wherein the interruption is provided at least in the inorganic passivation layer system.

4. The semiconductor die of claim 3, wherein the organic layer is uninterrupted at the interruption position xᵢ and fills the interruption in the inorganic passivation layer system.

5. The semiconductor die of claim 2, wherein the interruption is provided at least in the organic layer.

6. The semiconductor die of claim 2, wherein the inorganic passivation layer system comprises a silicon nitride layer and a silicon oxide layer.

7. The semiconductor die of claim 2, wherein the organic layer is an imide layer.

8. The semiconductor die of claim 2, wherein an adhesion promoter layer is arranged below the organic layer on the inorganic passivation layer system.

9. The semiconductor die of claim 8, wherein the adhesion promoter layer at least one of is made of aluminum oxide or has a thickness of at most 30 nm.

10. The semiconductor die of claim 1, wherein the interruption is respectively spaced by at least 10% of a distance d from the lateral edge of the load pad and the inner lateral position x₂, the distance d being taken in the sectional plane between the lateral edge of the load pad and the inner lateral position x₂.

11. The semiconductor die of claim 1, wherein the metallization in the area of the load pad is formed with a step, the load pad having a first thickness t₁ laterally outside of the step and a second thickness t₂ laterally inside of the step, where t₁ is smaller than t₂.

12. The semiconductor die of claim 11, wherein the inner the lateral position x₂, to which the passivation system extends, is arranged laterally outside of the step, where the load pad has the thickness t₁.

13. The semiconductor die of claim 11, wherein an inorganic layer or layer stack covers a flank of the step.

14. The semiconductor die of claim 1, wherein the metallization comprises a copper layer.

15. The semiconductor die of claim 1, wherein a runner is formed aside the load pad in the metallization, the passivation system being uninterrupted above the runner.

16. A method of manufacturing a semiconductor die, comprising:
forming a device structure with a load terminal in a semiconductor body;
forming a metallization with a load pad on a first side of the semiconductor body; and
forming a passivation system on the metallization, which has an opening on the load pad, wherein an interruption is provided in at least one layer of the passivation system at an interruption position xᵢ between a lateral edge of the load pad and the opening.

17. The method of claim 16, wherein forming the passivation system on the metallization comprises:
forming an inorganic passivation layer system; and
forming an organic layer on the inorganic passivation layer system.

18. The method of claim 17, wherein the interruption is formed in the inorganic passivation layer system, by
providing a mask having an opening defining the interruption on the inorganic passivation layer system after forming the passivation system on the metallization; and
etching the interruption defined by the mask into the inorganic passivation layer system.

19. A method of manufacturing a semiconductor die, comprising:
forming a metallization with a load pad on a first side of a semiconductor body;
forming an inorganic passivation layer system on the metallization, which has an opening on the load pad; and
forming a protection layer with a thickness of at most 30 nm in the opening on the load pad.

20. The method of claim 19, comprising removing a temporary protection layer present on the metallization in the opening from the load pad prior to forming the protection layer.
